(19) United States
(12) Patent Application Publication
(10) Pub. No.: US 2010/0326716 A1
(43) Pub. Date: Dec. 30, 2010

(54) Core via for chip package and interconnect

(76) Inventors: Zhichao Zhang, Mesa, AZ (US); Kemal Aygun, Chandler, AZ (US); Guizhen Zheng, Phoenix, AZ (US)

Correspondence Address: INTEL CORPORATION;c/o CPA Global, P.O. BOX 52050, MINNEAPOLIS, MN, 55402, US

(21) Appl. No.: 12/459,082

(22) Filed: Jun. 26, 2009

(51) Int. Cl. H05K 1/11; H05K 3/10

(52) U.S. Cl. 174/262; 29/846

(57) ABSTRACT

In integrated circuit packages, core vias are created to provide electrical connections between circuitry on one face of the core substrate material with circuitry on an opposing face of the core substrate material. Provided are methods for forming a via in a packaging substrate and packaging substrates having core vias formed in the core substrate material. Methods for forma a core via in a packaging substrate in which a first hole is created through the core substrate and filled with a low permittivity filler material. A second co-axially aligned hole is then created in the low permittivity filler material wherein the second hole is smaller in diameter than the first hole. The second hole is then filled with conducting material to provide a conducting via through the core substrate material.

### BACKGROUND OF THE INVENTION

1. Field of the Invention

The embodiments of the present invention relate generally to semiconductor processing and integrated circuits, and more specifically to chip (or die) packaging and core vias.

2. Background Information

After an integrated circuit chip (also called a microelectronic circuit chip, chip, or die) has been manufactured, the chip is typically packaged in a manner that takes into account the operating environment supplied by the device in which it will reside. In general, packaging of chips involves a series of processes that separate a wafer (a semiconducting substrate on which a series of integrated circuit chips has been manufactured) into individual chips, places the chips in protective packaging, and provides electrical lead systems that allow the chips to be incorporated into electronic products. A die is typically an integrated circuit chip that has been diced or cut from a finished wafer. A chip may be packaged, for example, in an individual package, incorporated into a hybrid circuit (in multichip modules (MCMs)), or mounted directly on a board, a printed circuit board, or a chip-on-board (COB). Chip packaging can also variously be referred to as assembly, or the back-end processes.

The type of package that is used for a particular chip can have a significant impact on the performance of an assembled electronic device. As chips get smaller and faster, there is an ongoing need for innovative and cost effective packaging technologies that allow high speed input/output (HSIO) interconnections between chips and surrounding electronic devices.

### BRIEF DESCRIPTION OF THE FIGURES

FIG. 1 diagrams a fabrication process for a core via for package vertical interconnection.

FIG. 2 provides a flow diagram for a fabrication process for a core via for package vertical interconnection.

FIG. 3 graphs a comparison of the package vertical interconnect impedance mismatch from the core via and the land pad formed through different manufacturing processes.

FIGS. 4(a) and (b) provide the results of a full wave simulation model for (a) double drilled core via according to embodiments of the present invention and (b) a via created by coax PTH manufacturing processes.

FIG. 5 provides a graph comparing the return loss for a core via created by double drilled core via methods according to embodiments of the present invention and coax PTH manufacturing processes.

### DETAILED DESCRIPTION OF THE INVENTION

Packaging of an integrated circuit chip can involve attaching it to a substrate (a packaging substrate) that, among other things, provides mechanical support and electrical connections between the chip and other electronic devices. A function of the package substrate is to allow the connection of a chip to a circuit board or directly to an electronic product. The substrate acts as an interposer and it allows the connections from the chip scale to the motherboard scale. Substrate types include cored substrates, including thin core, thick core (laminate BT (bismaleimide-triazine resin) or FR-4 type fibrous board material), and laminate core, as well as coreless substrates. Cored package substrates, for example, can be built up layer by layer around a central core, with layers of conductive material (usually copper) separated by layers of insulating dielectric, with interlayer connections being formed with through holes or microvias (vias).

A package substrate is a substrate to which an integrated circuit chip can be attached. The package substrate provides electrical connections to the chip. The electrical connections to the chip can be used to connect the chip to additional electronic devices, such as mother boards. Typically a package substrate is comprised of a base substrate material, called a core, on which electrical circuitry is manufactured or placed. Typically the core substrate is an insulated material, such as for example, an epoxy resin such as BT or FR-4 embedded with glass cloth reinforcement. The other materials that can be used as a core substrate include, glass fiber reinforced resin. Circuitry is built from conducting materials and insulating materials. Typical insulators used in the semiconductor industry include, for example, epoxy resin film polyimide (PI) and epoxy resin with silicon filler available from, for example, Ajinomoto Fine-Techno Co., Inc. Fort Lee, N.J., Hitachi Chemical Co., Ltd., Japan, and Sumitomo Electric USA, Inc., Los Angeles, Calif. Embodiments of the present invention are not limited to a particular type of insulating material that is used to fill a core via hole. Conducting materials include metals such as copper, gold, tungsten, and aluminum. Embodiments of the present invention are not limited to a particular type of conducting material that is used to fill a core via hole. Currently, copper is the conducting material that is most often chosen for forming conducting lines in the semiconductor industry.

Embodiments of the invention are useful for creating vias in package substrates in which the substrate core is fabricated with materials, for example, containing glass fiber reinforcement.

In general, a via is an opening created in a substrate that is filled with conducting material and used to connect circuits on various layers of a substrate to one another and or to the exterior of a substrate. In the case of a core via in a substrate, the core via is a hole through the core substrate filled with conducting material that can be used to connect electronic circuitry placed on one face of the substrate core with electronic circuitry placed on the opposite face of the substrate core. The via interconnection is sometimes referred to as a “vertical interconnect” in relation to other types of interconnects formed through different processes, such as, for example, layering processes, which are considered “horizontal interconnects.”

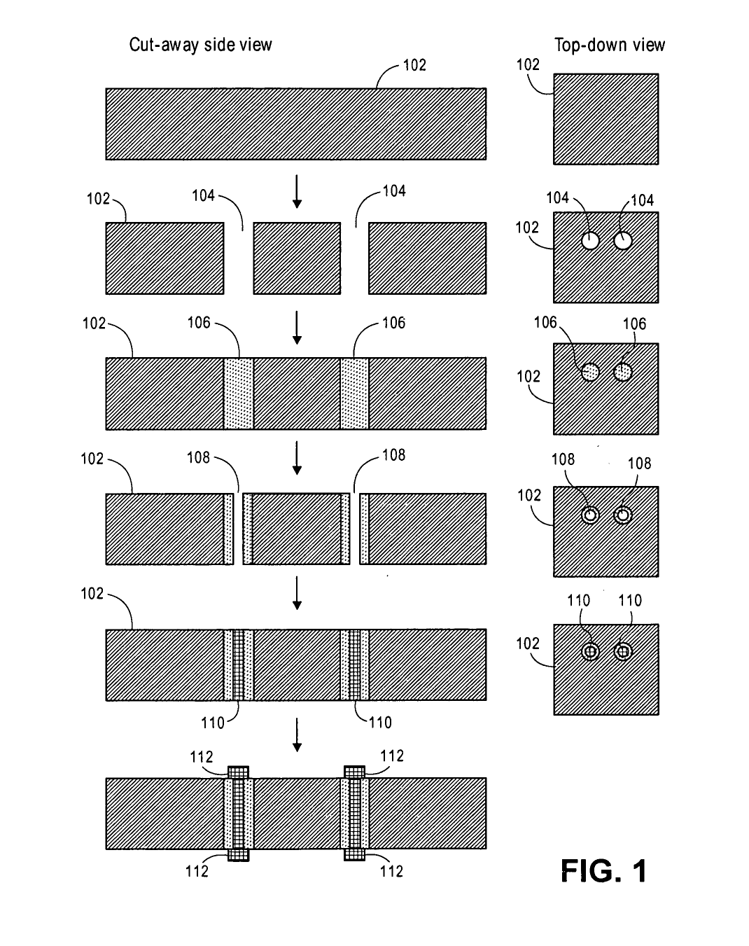

FIG. 1 diagrams a method for forming a core via in a substrate 102 for package vertical interconnect. In FIG. 1, a hole 104 with a diameter of several hundred microns is mechanically drilled through the package core substrate 102. Typically a hole 104 has a diameter of between 100 μm to 1000 μm, and more typically the diameter range is 250 μm to 300 μm. The hole can be drilled, for example, by using a mechanical drill bit, a water jet, or through a sand blasting technique. Filler material 106 is used to fill the hole 104. Filler material 106 preferentially is material having a low permittivity that is more easily drilled through laser drilling methods than the glass fiber reinforced epoxy resins, and is a material such as for example, an epoxy resin that does not contain glass fiber reinforcement. The filler material 106 is deposited in the hole using standard semiconductor packaging techniques, such as for example, squeegee printing or stencil printing with squeegee. A second hole 108 is then drilled through the filler material 106 in first hole using either mechanical drilling processes or laser drilling processes, depending on the dimensions of the hole to be created. The second hole is co-axially aligned or nearly co-axially aligned with the first hole, to within 20% tolerance or more, so long as the second hole is contained within the dimensions of the first hole. The second hole is smaller in diameter than the first hole and contained within the dimensions of the first hole. The double drilling allows relatively small conducting vias to be formed through thick cores. Typically, the diameter of the laser drilled hole (the second hole 108) is between 50 μm and 200 μm, and more typically between 75 and 125 μm. In this example, the size of the hole is 100 μm. In the past, typically, thick core materials required mechanical drilling techniques. Laser drilling techniques are capable of forming smaller diameter holes than mechanical drilling techniques. Mechanical drilling techniques are typically capable of forming holes having diameters in the 100 μm to 1000 μm range. Forming holes using mechanical drilling techniques that are less than about 100 μm can present challenges. Additionally, mechanical drilling is typically more expensive than laser drilling because fewer samples can be drilled per unit time and the drill bit is subject to mechanical damage. Advantageously, embodiments of the present invention allow smaller vias to be formed in thick cores. Conducting material 110 is deposited in the second hole 108 and capped 112 with conducting material to form the core via 110. Capping typically is done as part of a patterning process. Conducting materials include metals such as copper, aluminum, and tungsten. The conducting material is deposited in the second hole by physical vapor deposition (PVD), electrochemical deposition (ECD), or electrical plating, for example. The relatively small size of the conducting via reduces package core via capacitance as compared to larger sized core vias and benefits the package HSIO performance.

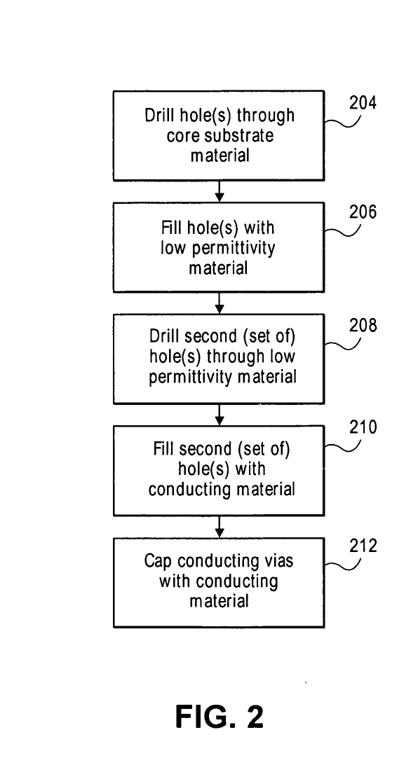

FIG. 2 provides a process diagram for a general method according to embodiments of the invention for forming core vias. In FIG. 2, box 204, a core substrate material is provided and one or more holes are drilled through the substrate in regions in which vias are to be created. The one or more holes are then filled with a material having a low permittivity (box 206), according to standard IC chip packaging techniques. A second set of one or more holes is drilled through the low permittivity material that was used to fill the first set of one or more holes (box 208) form holes through the core substrate that are surrounded by material having a low permittivity. The second (set of) hole(s) that were formed in the low permittivity material are then filled with conducting material, such as a metal, (box 210) using standard semiconductor techniques, such as PVD and ECD techniques for metals. Typically, the conducting material is a metal such as copper, aluminum, or tungsten. The conducting vias that are now formed in the core substrate are capped with conducting material (box 212).

Typically, package core substrates (e.g., thick package core substrates, such as laminate core substrates) are comprised of glass fiber or glass cloth filled epoxide. The typical thickness of the core substrates useful in the present invention is 100 to 1200 μm, or 250 to 1000 μm.

Mechanical drilling to form holes in package substrates can be performed, for example, using mechanical drill bits and by water drilling and sand blasting techniques. Laser drilling to form vias can be performed, for example, using an excimer laser, an ultraviolet (UV) laser, or a CO₂ laser. More generally, any type of laser that is suitable for the process of via formation may be used to form vias.

In general, low permittivity materials are materials that do not contain glass fiber or other materials that can cause laser diffraction. Exemplary low permittivity filler materials include epoxy resin film polyimide (PI), and epoxy resin with silicon filler available from, for example, Ajinomoto Fine-Techno Inc., Co., Hitachi Chemical Co., Ltd., Japan, Sumitomo Electric USA, Inc.

Conducting materials include, for example, metals such as copper and aluminum. Standard semiconductor techniques are employed to deposit metals in holes and form caps. For example, techniques such as, physical vapor deposition (PVD) (also known as sputtering), electrochemical deposition (ECD), and electrical plating are employed.

Typically holes formed in the package core substrate have a somewhat tapered cylindrical shape from the side to the middle of the core. This shape tends to be a product of laser light attenuation toward the center of the core as the hole is drilled. Thus, the shape is, in general, a product of the technique(s) used to form the hole. Holes formed, do not necessarily have to be circular in shape when viewed from above, they may also be elliptical, for example. Advantageously, embodiments of the present invention are not limited to holes having a particular shape.

Embodiments of the present invention provide cost advantages and equivalent or improved electrical performance over via-forming techniques such as mechanical drilling, micro-via stackup, and coax PTH (coaxial plated through hole) manufacturing methods. For example, standard PTH employs mechanical drilling to drill through the package core material. The cost is higher for mechanical drilling typically because drill speed is limited and the number of holes that can be created in a given period of time is smaller for mechanical drilling techniques than for laser drilling techniques. Additionally, the hole size created through mechanical drilling techniques is limited by the drill thickness. Further, embodiments of the present invention avoid the copper plating and cost adder associated with coax PTH processes in which copper plating is applied after holes are drilled in the package core substrate. The ability to achieve a smaller via size through a thicker core according to embodiments of the present invention allows for reductions in the core via-related capacitance and impedance mismatch for improved package return loss and HSIO performance.

The impedance of a core via formed through PTH processes is usually found to be below the nominal impedance of horizontal interconnects (transmission lines in the form of microstrips, striplines, and co-planar waveguides) that typically have well controlled impedance, because of capacitive properties of the core via. Solutions for reducing the capacitance of a core via include shrinking the PTH (Plated Through Hole) size or increasing the PTH to surrounding ground void size. The PTH can be fabricated by mechanically drilling the smaller PTH through the core material. The PTH size is limited by mechanical drilling capability, and the minimum drill size is usually about 100-125 μm in diameter. In micro-via stackup type technology, the core is fabricated using buildup processes and the core via is drilled using a laser. However, laser drilling techniques cannot be used with core material that is too thick, such as with core materials that are 400 μm and above in thickness. Usually the dielectric thickness in each core layer is below 60 μm which requires using an increased number of core layers to reach a desired electrical performance target and substrate thickness required for assembly. In coax PTH, the PTH is created in the form of a co-axis cable. The core is first mechanically drilled and then copper plated. The resulting copper-plated hole is filled with non-conducting filler material. A second hole is formed through the filler material either mechanically or using a laser. The smaller second hole is then filled with copper and becomes the inner conductor of the coax PTH.

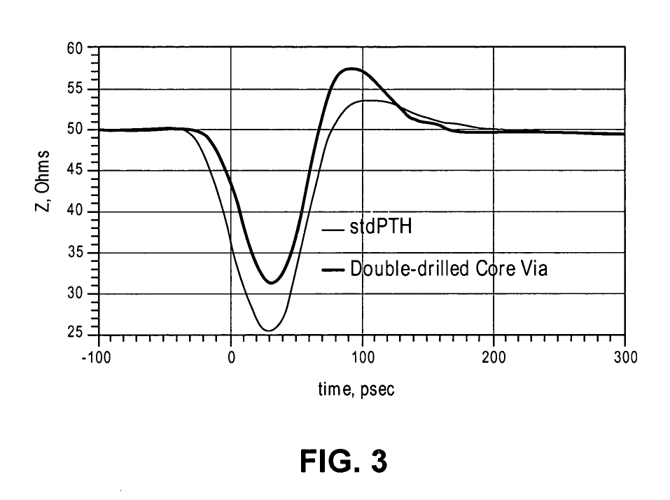

FIG. 3 provides a comparison of the impedance profile of a package core via/PTH formed according to several processes: standard PTH, having a PTH pad diameter of 400 μm and a PTH drill diameter of 250 μm, and a double drilled process according to embodiments of the present invention. In general, a high speed signal traveling through a medium requires the impedance of the medium to be consistent and a mismatch in impedance causes some of the signal to be reflected. An impedance profile, such as that in FIG. 3, shows how impedance varies with time and impedance varies over a signal path. In an ideal case, the curve should be as flat as possible indicating that the impedance is the same along the entire propagation pathway. However, discontinuity cannot be avoided completely. The curve labeled “double-drilled core via” represents the simulated behavior of a core via formed by double drilling according to embodiments of the present invention. As can be seen from FIG. 3, less impedance mismatch is observed for the double drilled core via than for the std PTH core via (the second curve, labeled “stdPTH” represents the standard PTH process). The standard PTH process has bulkier dimensions and more impedance mismatch. The graph was made using software called Advanced Design System (ADS) available from Agilent Technologies, Inc., Santa Clara, Calif. The ADS software allows the simulation the electronic behavior of packaging designs such as the ones shown here. The parameters are based on single-ended signal link with terminal impedance of 42.5 Ohm. Differential signal link shows similar behavior. The impedance requirement in the channel will impact the optimization and dimension choice of the double-drilled via to achieve optimal electrical performance.

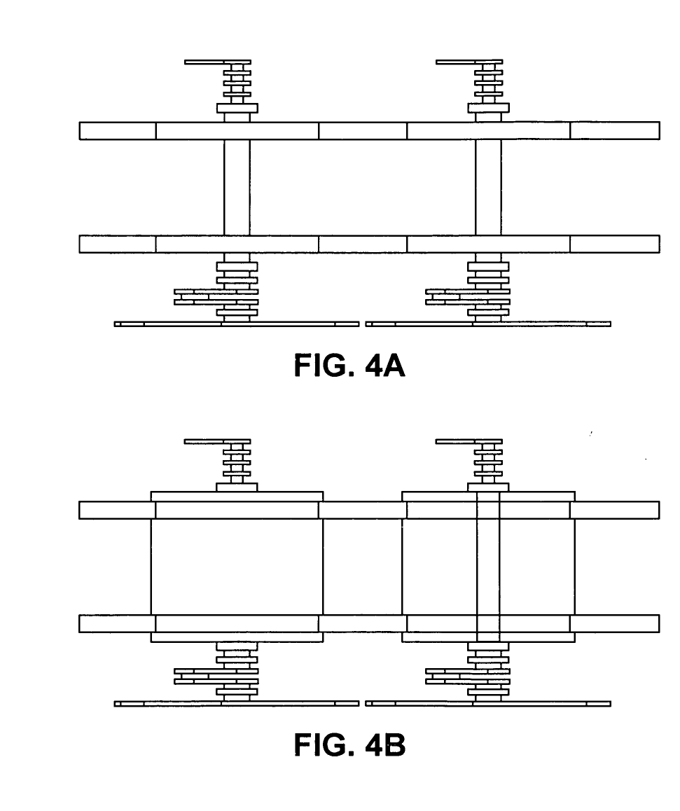

FIG. 4 provides a full wave electromagnetic wave simulation model that compares a double drilled core via according to embodiments of the invention with a coax PTH. As can be seen from FIG. 4 the double-drilled core via (shown on the left, FIG. 4(a)) does not have a copper wall as shown in the coax-PTH structure on the right (FIG. 4(b)). FIG. 4 shows the actual dimension of the core via. The double-drilled core via takes less space and allows higher core via density within a package core. FIG. 4 was rendered using simulation software called High Frequency Structure Simulator (HFSS) available from Ansoft, Pittsburgh, Pa. FIG. 4 shows the geometrical structures of and the difference between double-drilled via and coax-PTH in HFSS.

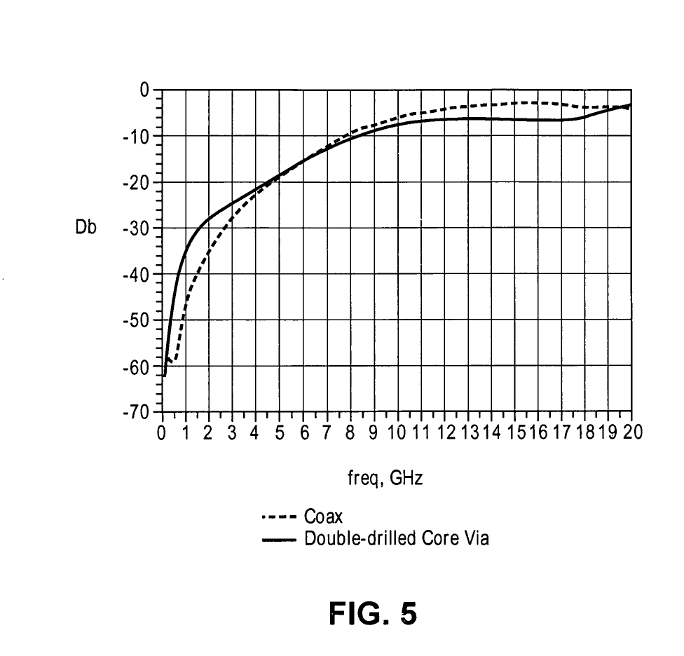

FIG. 5 provides a graph comparing the return loss of a package core via/PTH formed according to double-drilled core via processes of the present invention with coax PTH processes. In general, return loss is the ratio of the amplitude of reflected wave to the amplitude of the incident wave through a transmission line in which an impedance mismatch exists. Return loss is measured in decibel (dB). It is desirable to have a return loss that is as small as possible so that the majority of the signal reaches the receiver. Embodiments of the present invention providing the double drill design allow a tighter pitch (placement) between via holes in a core substrate. As can be seen from FIG. 5, skipping the metal plating step of coaxial PTH manufacturing methods does not significantly impact the performance of the core via. FIG. 5 was rendered using ADS software by plotting the s-parameters (the s-parameter is a scattering parameter which is a standard definition in electrical engineering that describes the electrical behavior of linear electrical networks) generated in HFSS. The simulation assumes the outer drill has a diameter of 666 μm and inner conductor has a diameter of 100 μm. Copper is used to form the vias. The s-parameter representing the reflection (return loss) is evaluated specifically

1. A method for forming a via in a packaging core substrate comprising,
providing a substrate in which one or more vias are to be formed;
creating a first hole through the substrate;
filling the first hole in the substrate with a low-permittivity filler material wherein the first hole is not plated with a metal before the low-permittivity filler material is placed in the first hole;
creating a second hole within the first hole through the non-conducting filler material wherein the second hole is smaller in diameter than the first hole; and
filling the second hole with a conducting material.

2. The method of claim 1 wherein the first hole through the substrate has a diameter between 100 μm to 1000 μm.

3. The method of claim 1 wherein the second hole through the non-conducting filler material has a diameter between 50 μm and 200 μm.

4. The method of claim 1 wherein the substrate is comprised of a material selected from the group consisting of epoxy resin embedded with glass fiber and epoxy resin embedded with glass fiber cloth.

5. The method of claim 1 wherein the substrate in one dimension has a thickness of between 100 and 1200 μm, wherein the first core via hole has a length, and wherein the length of the first core via hole is defined by the thickness of the substrate.

6. The method of claim 1 wherein the substrate in one dimension has a thickness of between 250 and 1000 μm, wherein the first core via hole has a length, and wherein the length of the first core via hole is defined by the thickness of the substrate.

7. The method of claim 1 wherein the non-conducting filler material is an epoxy resin.

8. The method of claim 1 also including placing a cap of conducting material on the second hole that is filled with conducting material.

9. The method of claim 1 wherein the second co-axially aligned hole is created through a laser drilling process.

10. An integrated circuit packaging substrate comprising,
a core substrate having at least one via through the core wherein the via is a hole through the substrate that is filled with a non-conducting material wherein the non-conducting material filling the hole in the substrate is in intimate contact with the substrate and wherein there is a second hole through the non-conducting material that is within the first hole and the second hole is filled with a conducting material, and
electronic circuitry capable of providing an electronic connection to an integrated circuit chip.

11. The integrated circuit packaging substrate of claim 10 wherein the first hole through the substrate has a diameter between 100 μm to 1000 μm.

12. The integrated circuit packaging substrate of claim 10 wherein the second hole through the non-conducting filler material has a diameter between 50 μm and 200 μm.

13. The integrated circuit packaging substrate of claim 10 wherein wherein the substrate in one dimension has a thickness of between 100 and 1200 μm, wherein the first core via hole has a length, and wherein the length of the first core via hole is defined by the thickness of the substrate.

14. The integrated circuit packaging substrate of claim 10 wherein the substrate in one dimension has a thickness of between 250 and 1000 μm, wherein the first core via hole has a length, and wherein the length of the first core via hole is defined by the thickness of the substrate.

15. The integrated circuit packaging substrate of claim 10 wherein the non-conducting filler material is epoxy resin.

16. The integrated circuit packaging substrate of claim 10 also including a cap of conducting material on the second hole that is filled with conducting material.

17. The integrated circuit packaging substrate of claim 10 wherein the conducting material is selected from the group consisting of copper and aluminum.
